(19) United States
(12) Patent Application Publication
(10) Pub. No.: US 2023/0298986 A1
(43) Pub. Date: Sep. 21, 2023

(54) PACKAGE SUBSTRATE AND MANUFACTURING METHOD THEREOF

(71) Applicant: AaltoSemi Inc., Nanjing City (TW)

(72) Inventors: Min-Yao CHEN, Nanjing City (TW); Sung-Kun LIN, Nanjing City (TW); Andrew C. CHANG, Nanjing City (TW)

(21) Appl. No.: 18/180,502

(22) Filed: Mar. 8, 2023

(30) Foreign Application Priority Data
Mar. 16, 2022 (TW) 111109619

(51) Int. Cl. H01L 23/498; H01L 21/48

(52) U.S. Cl. CPC H01L 23/49827; H01L 23/49822; H01L 21/4857; H01L 21/486

(57) ABSTRACT

A package substrate and the manufacturing method thereof are provided. The method includes encapsulating a circuit layer and a conductive pillar on the circuit layer with an insulating layer, and then forming a groove in the insulating layer corresponding to the conductive pillar, so as to form a routing layer in the groove, so there is no need for drilling to make blind vias. Therefore, the alignment problem of conventional circuits and conductive blind vias can be avoided.

### BACKGROUND

### 1. Technical Field

The present disclosure relates to a semiconductor packaging technology. In particular, the present disclosure relates to a package substrate with embedded traces and manufacturing method thereof.

### 2. Description of Related Art

With the booming development of electronic industry, electronic products tend to be thin and light, while in terms of function, they tend to be developed in the direction of high performance, high functionality and high speed. Therefore, in order to meet the demand for high integration and miniaturization of semiconductor devices, package substrates with high density and fine pitch circuits are often used in the packaging process.

As shown in FIG. 1, a conventional package substrate 1 includes a core layer 10 having a plurality of conductive pillars 100, a plurality of dielectric layers 11 formed on two opposite sides of the core layer 10, and a circuit layer 12 formed on each of the dielectric layers 11, wherein the circuit layers 12 on the two opposite sides of the core layer 10 are electrically connected by the plurality of conductive pillars 100, wherein the circuit layers 12 are electrically connected to the conductive pillars 100 by conductive blind vias 120.

However, in the conventional package substrate 1, the conductive blind vias 120 are made by forming holes on the dielectric layers 11 by laser or machine drilling, and then filling the holes with conductive materials. Therefore, the holes are often misaligned due to operation errors during the process of forming the holes, resulting in the holes not being formed in the intended places, thereby making the conductive blind vias 120 unable to effectively connect the conductive pillars 100 to the circuit layers 12, and causing the poor electrical connection of the package substrate 1.

Hence, there is an urgent need to overcome the problems of the above-mentioned conventional technology.

### SUMMARY

In view of the above-mentioned problems of conventional technology, the present disclosure provides a package substrate, comprising: an insulating layer, wherein a groove is formed on a side of the insulating layer; a circuit layer embedded on another side of the insulating layer; at least one conductive pillar embedded in the insulating layer to connect to the circuit layer; and a routing layer formed in the groove to connect to the conductive pillar.

The present disclosure further provides a method of manufacturing a package substrate, the method comprising: forming a circuit layer and at least one conductive pillar on a carrier sequentially; forming an insulating layer on the carrier, wherein the circuit layer and the conductive pillar are encapsulated by the insulating layer; forming a blocking layer having a plurality of open areas on the insulating layer, wherein a portion of a surface of the insulating layer is exposed from the open areas; forming grooves on the surface of the insulating layer corresponding to the open areas, wherein each of the at least one conductive pillar is exposed from one of the grooves; removing the blocking layer; and forming a routing layer in the grooves.

In the above-mentioned method, the blocking layer is a metal layer.

The above-mentioned method further comprises performing a layer increase operation on the routing layer.

The above-mentioned package substrate and method further comprise: when forming the routing layer in the grooves, forming an alignment portion on the insulating layer together with the routing layer, wherein the routing layer is covered by the alignment portion. For example, the alignment portion and the routing layer are integrally formed.

In the above-mentioned package substrate and method, the routing layer is flush with the surface of the insulating layer.

In view of the above, the package substrate of the present disclosure and the manufacturing method thereof form grooves in the positions on the insulating layer corresponding to the conductive pillars, so as to form the routing layer in the grooves. Therefore, compared to conventional technology, the present disclosure does not need to drill holes to form blind vias, thus avoiding the alignment problem of conventional circuits and conductive blind vias.

### BRIEF DESCRIPTION OF THE DRAWINGS

FIG. 1 is a schematic cross-sectional view of a conventional package substrate.

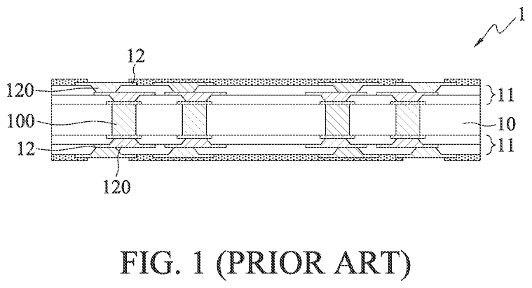

FIG. 2A to FIG. 2I are schematic cross-sectional views illustrating a method of manufacturing a package substrate according to the present disclosure.

FIG. 2J is a schematic cross-sectional view illustrating another manufacturing method of FIG. 2I.

FIG. 2K is a schematic partial enlarged top view of FIG. 2I.

FIG. 3A to FIG. 3B are schematic cross-sectional views illustrating the subsequent manufacturing process of FIG. 2I.

### DETAILED DESCRIPTION

The following is an illustration of the manner in which the present disclosure is implemented by means of embodiments, so that persons skilled in the art can easily understand the other advantages and effects of the present disclosure based on the disclosure in this specification.

It should be noted that the structures, proportions, sizes, etc. of the drawings accompanying this specification are intended for illustrating the contents disclosed in the specification for persons skilled in the art to understand and read the disclosed contents, not intended for limiting the conditions under which the present disclosure can be implemented, and therefore have no substantive technical significance. Any modification of structures, change of proportions, or adjustment of sizes, without affecting the efficacy the present disclosure can produce and the purpose the present disclosure can achieve, shall still fall within the scope of the technical contents disclosed by the present disclosure. In addition, terms such as “on,” “above,” “up,” “below,” “down,” “one” and “a” are for the convenience and clarity of description and are not intended to limit the scope of implementation of the present disclosure. The changes or adjustments of the relative relationship thereof, without substantial changes in the technical contents, should also be considered as the scope of implementation of the present disclosure.

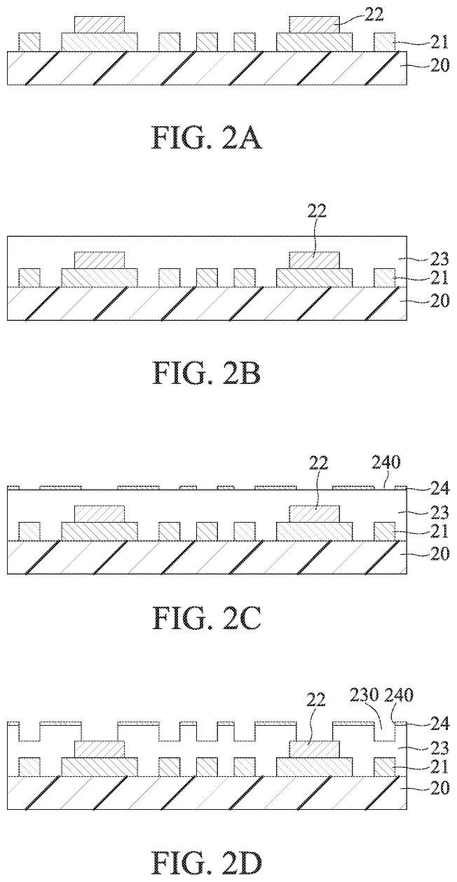

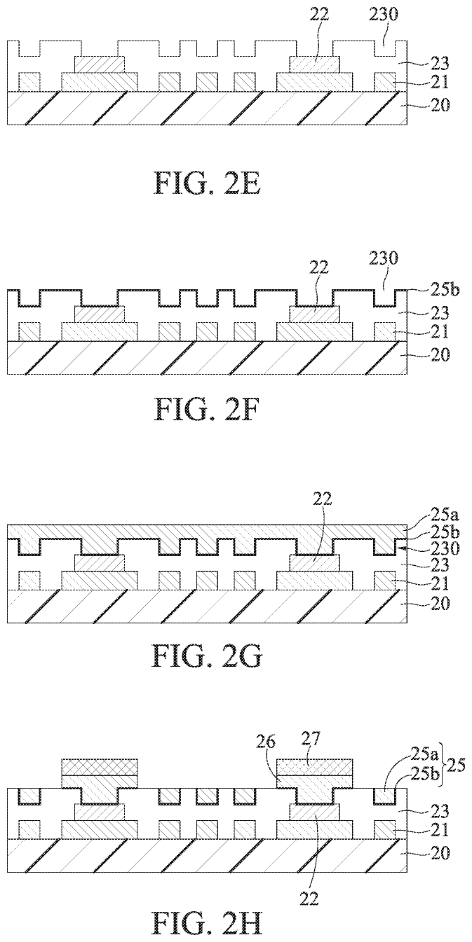

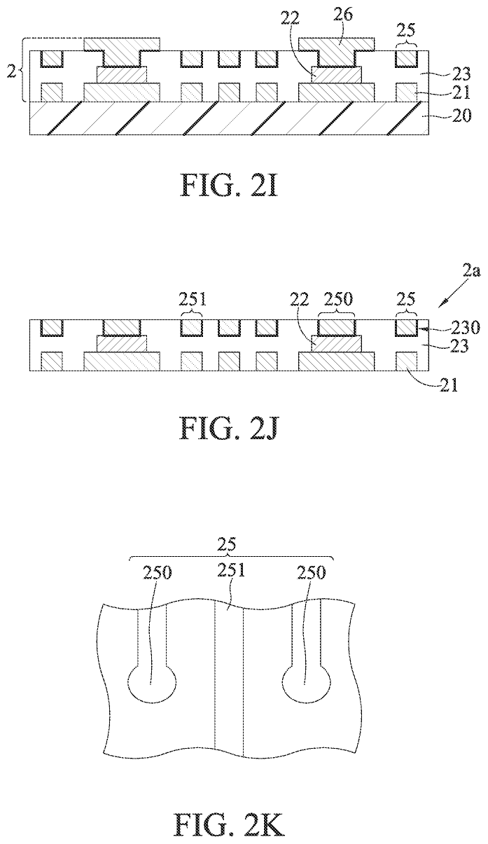

FIG. 2A to FIG. 2I are schematic cross-sectional views illustrating a method of manufacturing a package substrate 2 according to the present disclosure. In an embodiment, the package substrate 2 is of an aspect either with a core layer or without a core layer (coreless).

As shown in FIG. 2A, a circuit layer 21 and at least one conductive pillar 22 are sequentially formed on a carrier 20.

In an embodiment, the carrier 20 is a consumable material such as a temporary carrier plate. In addition, the circuit layer 21 and the conductive pillar 22 may be formed by electroplating copper, for example, by first forming the circuit layer 21 on the carrier 20 and then forming patterned photoresist (not shown) on the carrier 20 and the circuit layer 21, wherein a portion of the circuit layer 21 is exposed from the patterned photoresist. Next, the conductive pillar 22 is formed on the exposed surface of the circuit layer 21, and finally the patterned photoresist is removed.

As shown in FIG. 2B, an insulating layer 23 is formed on the carrier 20, so that the circuit layer 21 and the conductive pillar 22 are encapsulated by the insulating layer 23.

In an embodiment, the material forming the insulating layer 23 is for instance an Ajinomoto Build-up Film (ABF) or other suitable dielectric material. For example, the insulating layer 23 is formed on the carrier 20 by lamination.

As shown in FIG. 2C, a blocking layer 24 with a plurality of open areas 240 is formed on the insulating layer 23 so that the open areas 240 expose a portion of the surface of the insulating layer 23.

In an embodiment, the material forming the blocking layer 24 is for instance copper or other suitable metal material. For example, the copper material is first formed on all of the top surface of the insulating layer 23 by sputtering, then patterned photoresist (not shown) is formed on the copper material, and exposure development is performed so that a portion of the copper material is exposed from the patterned photoresist, then the copper material exposed from the patterned photoresist is removed by etching to form the open areas 240, and finally the patterned photoresist is stripped so that the remaining copper material becomes the blocking layer 24.

As shown in FIG. 2D, grooves 230 are formed on the surfaces of the insulating layer 23 corresponding to the open areas 240 so that each conductive pillar 22 is partially exposed by a groove 230.

In an embodiment, a portion of the insulating layer 23 is removed by plasma etching or chemical etching to form the grooves 230.

As shown in FIG. 2E, the blocking layer 24 is removed by etching to expose the insulating layer 23, and then the surfaces of the insulating layer 23 and the grooves 230 are subject to desmear operation.

As shown in FIG. 2F to FIG. 2G, a metal material 25a is formed on the insulating layer 23, and the metal material 25a is filled into the grooves 230 to contact the conductive pillars 22.

In an embodiment, a seed layer 25b such as copper material may be formed on the surfaces of the insulating layer 23 and the grooves 230, as shown in FIG. 2F, and then the metal material 25a may be formed by electroplating a copper material by means of the seed layer 25b, as shown in FIG. 2G.

As shown in FIG. 2H, at least a portion of the metal material 25a on the surface of the insulating layer 23 and the seed layer 25b under the portion of the metal material 25a are removed, while the metal material 25a and the seed layer 25b in the grooves 230 are retained to be a routing layer 25 (e.g., a wiring layer).

In an embodiment, when forming the routing layer 25 in the grooves 230, at least a portion of the metal material 25a on the surface of the insulating layer 23 and the seed layer 25b under the portion of the metal material 25a may be retained to form an alignment portion 26 covering the routing layer 25 on the insulating layer 23 together. For example, a patterned photoresist 27 is first formed on a portion of the surface of the metal material 25a, and then the metal material 25a surrounding the photoresist 27 and the seed layer 25b under the surrounding metal material 25a are removed so that the metal material 25a and the seed layer 25b under the photoresist 27 form a ring-like alignment portion 26. Therefore, the alignment portion 26 and the routing layer 25 are integrally formed.

Further, the routing layer 25 is flush with the top surface of the insulating layer 23.

As shown in FIG. 2I, the photoresist 27 is removed to expose the alignment portion 26. In the subsequent process, the carrier 20 may be removed, so that the circuit layer 21 is exposed from and flush with the bottom surface of the insulating layer 23, as shown in FIG. 2J.

In an embodiment, if the routing layer 25 is the outermost circuit configuration, the manufacturing of the alignment portion 26 can be omitted, such that after forming the metal material 25a as shown in FIG. 2G, the metal material 25a on the surface of the insulating layer 23 may be removed to obtain a package substrate 2a as shown in FIG. 2J.

Therefore, the manufacturing method of the present disclosure uses the conductive pillars 22 to pad and raise the circuit structure and then forms the grooves 230 and the embedded traces (i.e., the routing layer 25) on the insulating layer 23 by plasma etching or chemical etching, thus the conventional laser drilling process can be omitted.

Further, the manufacturing method of the present disclosure first forms the grooves 230 by means of the blocking layer 24 so that the routing layer 25 can be embedded in the insulating layer 23 to facilitate the design of fine-pitch/fine-trace.

Moreover, traces 251 and blind via portions 250 (which connect to the conductive pillars 22) of the routing layer 25 are formed in the same layer, as shown in FIG. 2K, thus avoiding the position tolerance problem of the traces 251 and the blind via portions 250. Hence, the landless via configuration (as shown in FIG. 2J, the width of the blind via portion 250 is less than the width of the conductive pillar 22) can be designed to enhance the routing/wiring density.

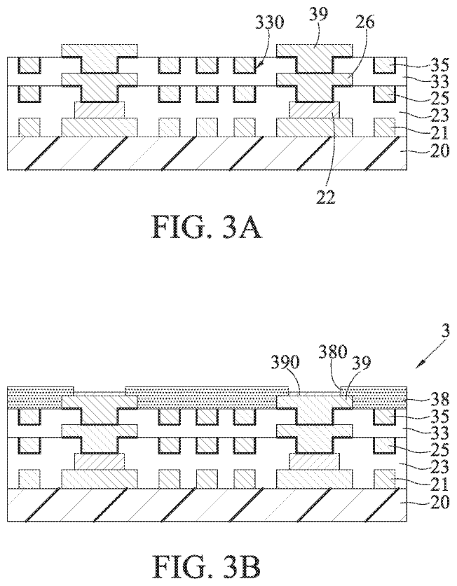

In addition, in another embodiment, following the process shown in FIG. 2I, the process shown in FIG. 2B to FIG. 2I is repeated to increase the layers to form a plurality of routing layers 35, as shown in FIG. 3A, and an insulating protective layer 38 with a plurality of openings 380 may be formed on an outermost insulating layer 33, such as a package substrate 3 shown in FIG. 3B. For example, on the outermost routing layer 35, the metal material originally intended to form the alignment portion may be designed as a plurality of pads 39 exposed by the openings 380 to serve as contacts. Further, a surface treatment layer 390 may be formed on the pads 39 in the openings 380.

Therefore, the manufacturing method of the present disclosure can accurately form grooves 330 of the insulating layer 33 in predetermined positions during the layer increase operation by means of the design of the alignment portion 26, thus avoiding the problem of misalignment due to operation errors.

In addition, the embedded traces (i.e., the routing layer 35) may be made in any one of the layers of the layer increase operation, so that the adhesion of the routing layer 35 can be improved to avoid scratches in the process and to improve reliability.

It should be understood that the present disclosure may form the alignment portion 26 in accordance with the requirements of the layer increase operation, without particular limitation.

The present disclosure provides a package substrate 2, 2a, 3, comprising: an insulating layer 23 having two opposite sides, a circuit layer 21 embedded in the insulating layer 23, at least one conductive pillar 22 embedded in the insulating layer 23, and at least one routing layer 25 embedded in the insulating layer 23.

A groove 230 is formed on one side of the insulating layer 23.

The circuit layer 21 is embedded on the other side of the insulating layer 23.

The conductive pillar 22 is embedded in the insulating layer 23 to connect to the circuit layer 21.

The routing layer 25 is formed in the groove 230 to connect to the conductive pillar 22.

In an embodiment, the package substrate 2, 3 further includes at least one alignment portion 26 disposed on the insulating layer 23 and covering the routing layer 25. For example, the alignment portion 26 is integral with the routing layer 25.

In an embodiment, the routing layer 25 is flush with a surface of the insulating layer 23.

In summary, the package substrate of the present disclosure and the manufacturing method thereof embed the routing layer in the insulating layer via the design of the grooves, thus eliminating the need for conventional drilling process. Therefore, the present disclosure not only facilitates the design of fine-pitch/fine-trace, but also avoids the alignment problem of conventional circuits and conductive blind vias.

The above embodiments are intended to exemplify the principles of the present disclosure and its effects, and are not intended to limit the present disclosure. Any person skilled in the art may modify the above embodiments without violating the spirit and the scope of the present disclosure. Accordingly, the scope of protection of the present disclosure shall be as set forth in the following claims.

What is claimed is:

1. A package substrate, comprising:
an insulating layer, wherein a groove is formed on a side of the insulating layer;
a circuit layer embedded on another side of the insulating layer;
at least one conductive pillar embedded in the insulating layer to connect to the circuit layer; and
a routing layer formed in the groove to connect to the conductive pillar.

2. The package substrate of claim 1, further comprising an alignment portion disposed on the insulating layer and covering the routing layer.

3. The package substrate of claim 2, wherein the alignment portion and the routing layer are integrally formed.

4. The package substrate of claim 1, wherein the routing layer is flush with a surface of the insulating layer.

5. A method of manufacturing a package substrate, comprising:
forming a circuit layer and at least one conductive pillar on a carrier sequentially;
forming an insulating layer on the carrier, wherein the circuit layer and the conductive pillar are encapsulated by the insulating layer;
forming a blocking layer having a plurality of open areas on the insulating layer, wherein a portion of a surface of the insulating layer is exposed from the open areas;
forming grooves on the surface of the insulating layer corresponding to the open areas, wherein each of the at least one conductive pillar is exposed from one of the grooves;
removing the blocking layer; and
forming a routing layer in the grooves.

6. The method of claim 5, wherein the blocking layer is a metal layer.

7. The method of claim 5, further comprising:
when forming the routing layer in the grooves, forming an alignment portion on the insulating layer together with the routing layer, wherein the routing layer is covered by the alignment portion.

8. The method of claim 7, wherein the alignment portion and the routing layer are integrally formed.

9. The method of claim 5, wherein the routing layer is flush with the surface of the insulating layer.

10. The method of claim 5, further comprising:
performing a layer increase operation on the routing layer.
